(19) United States
(12) Patent Application Publication
(10) Pub. No.: US 2004/0012939 A1
(43) Pub. Date: Jan. 22, 2004

(54) EMI shielding apparatus

(75) Inventors: Peter Cuong Dac Ta, Hayward, CA (US); Vernon P. Bollesen, San Jose, CA (US); Sergiu Radu, Fremont, CA (US)

Correspondence Address: B. Noel Kivlin, Meyertons, Hood, Kivlin, Kowert & Goetzel, P.C., P.O. Box 398, Austin, TX, 78767, US

(73) Assignee: Sun Microsystems, Inc.

(21) Appl. No.: 10/413,429

(22) Filed: Apr. 14, 2003

Related U.S. Application Data
(63) Continuation of application No. 10/097,946, filed on Mar. 14, 2002, now abandoned.

(51) Int. Cl. H05K 7/14; H05K 7/18

(52) U.S. Cl. 361/800

(57) ABSTRACT

A shielding apparatus for containing electromagnetic energy is disclosed. In one embodiment, a shield includes a plurality of sides, each side having a top and a bottom. A flange may extend from the top of the sides. A plurality of tabs extend from the flanges. The tabs include a first, second, and third portions. The first portion extends directly from the flange. The second portion extends at an angle from the first portion relative to the plane of the first portion and the flange. The longitudinal axis of the second portion is parallel to its associated flange or side. A third portion extends from the second portion, at an angle relative, to the second portion. A heat sink coated with an electrically conductive material may be mounted such that a bottom side of the heat sink is in contact with the plurality of tabs.

### BACKGROUND OF THE INVENTION

1. Field of the Invention

This invention relates to electronic systems, and more particularly, to the shielding of components which generate electromagnetic noise in electronic systems.

2. Description of the Related Art

A common problem encountered in electronic and computer systems is electromagnetic induction (EMI). EMI may be defined as the production of an electromotive force (i.e. a voltage) in a circuit or conductor by a change in electromagnetic flux linking with the circuit or conductor. EMI in many cases can interfere with the operation of both analog and digital electronic systems. In analog systems, unwanted noise resulting from EMI may interfere with other analog signals. In digital systems, EMI may induce voltages that result in an incorrect logic value being transmitted or read, or other types of erroneous operation.

High-frequency electronic systems may be especially susceptible to EMI. One example of a high-frequency system susceptible to EMI is a modern computer system. Processors in current computer systems often times operate with a clock speeds of 1 GHz or greater. A processor running at such a clock speed may produce a very high level of electromagnetic energy, which may adversely affect the operation of the computer system in which it is implemented.

One method of preventing the adverse effects of EMI is to use shielding. Often times, a metal shield or enclosure is placed around components (e.g. microprocessors) which generate a significant amount of electromagnetic energy. The metal shield or enclosure may contain a significant amount of the generated electromagnetic energy within its confines, thereby protecting nearby components from EMI. However, it is still possible that some electromagnetic energy will escape the confines of the shield. In some cases, the amount of electromagnetic flux leaking from the shield may be negligible. However, in some active components that operate at high frequencies, the amount of leakage flux may become significant. The leakage flux escaping from the shielding may thus result in EMI affecting surrounding circuitry.

The need to shield a component from radiating electromagnetic energy may exacerbate other problems. One such problem is heat generation. An EMI shield may trap heat within its confines. This is especially true for enclosure type shields. An enclosure type shield may trap a large amount of the heat produced by the device(s) for the shield is used. In many cases, excess heat that is trapped by an EMI shield may adversely affect the operation of a shielded device. Thus, the requirement to properly shield a device in order to contain electromagnetic energy may often times conflict with the requirement to eliminate waste heat from the device.

### SUMMARY OF THE INVENTION

A shielding apparatus for containing electromagnetic energy is disclosed. In one embodiment, an EMI (electromagnetic induction) shield includes a plurality of sides, each side having a top and a bottom. A flange may extend perpendicularly from the top of each of the sides. A plurality of tabs may extend from each of the flanges. The tabs may include a first portion, a second portion, and a third portion. The first portion may extend directly from the flange, and may be coplanar with the flange. The second portion may extend from the first portion, and may be at an angle relative to the plane of the first portion and the flange. The longitudinal axis of the second portion may be parallel to its associated flange or side. A third portion may extend from the second portion. The third portion may extend at an angle relative to the second portion. A heat sink may be mounted such that its bottom side is in contact with the third portion. The heat sink may be coated with an electrically conductive material.

### BRIEF DESCRIPTION OF THE DRAWINGS

Other aspects of the invention will become apparent upon reading the following detailed description and upon reference to the accompanying drawings in which:

FIG. 1 is a perspective view of a printed circuit assembly including a processor having one embodiment of an electromagnetic induction (EMI) shield and a heat sink having a conductive coating;

FIG. 2 is a perspective view of one embodiment of an EMI shield;

FIG. 3A is a top view of one embodiment of an EMI shield;

FIG. 3B is a side view of one embodiment of an EMI shield; and

FIG. 4A is a cross section illustrating a flange and a plurality of tabs extending from one side of one embodiment of an EMI shield;

FIG. 4B is a side view illustrating a plurality of tabs for one embodiment of an EMI shield;

FIG. 4C is a top view illustrating a plurality of tabs for one embodiment of an EMI shield; and

FIG. 4D is a side view illustrating the coupling of one embodiment of a heat sink to the plurality of tabs for one embodiment of an EMI shield.

While the invention is susceptible to various modifications and alternative forms, specific embodiments thereof are shown by way of example in the drawings and will herein be described in detail. It should be understood, however, that the drawings and description thereto are not intended to limit the invention to the particular form disclosed, but, on the contrary, the invention is to cover all modifications, equivalents, and alternatives falling with the spirit and scope of the present invention as defined by the appended claims.

### DETAILED DESCRIPTION OF THE INVENTION

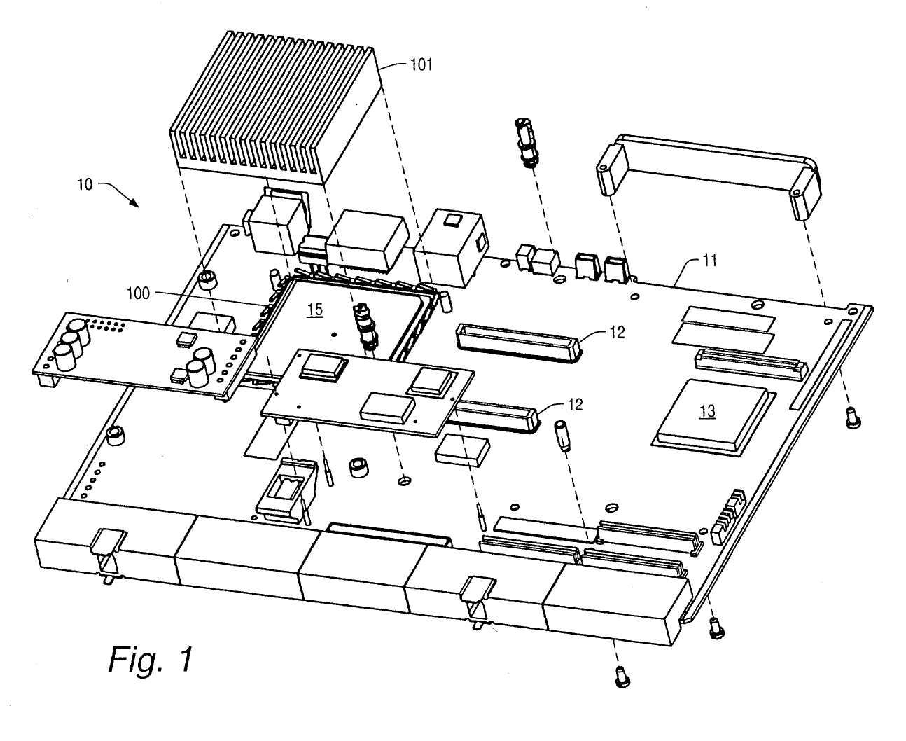

Moving now to FIG. 1, a perspective view of a printed circuit assembly including a processor having one embodiment of an electromagnetic induction (EMI) shield is shown. Printed circuit assembly (PCA) 10 may include a printed circuit board (PCB) 11 and various components mounted to it, such as connectors 12 and integrated circuit 13. Components such as integrated circuit 13 may be susceptible to electromagnetic interference. In particular, unwanted electromagnetic noise may interfere with the operation of integrated circuit 13 and other active components on PCA 10.

Processor 15 may also be mounted to PCB 11. Processor 15 may be partially enclosed by EMI shield 100. Heat sink 101 may also be mounted on top of processor 15. In one embodiment, heat sink 101 may be coated with an electrically conductive material, in contrast to other heat sinks that are coated with a black material designed to radiated heat. By coating heat sink 101 with an electrically conductive material, it may provide a dual function of radiating heat away from the processor and electromagnetic shielding.

The combination of EMI shield 100 and heat sink 101 may be effective in containing the spread of electromagnetic energy produced by processor 15. In particular, EMI shield 100 may be effective at containing electromagnetic energy generated near the periphery of processor 15, while heat sink 101 may be effective at containing electromagnetic energy generated in the central areas of processor 15. Containing electromagnetic energy generated by processor 15 may prevent EMI from adversely affecting the operation of other components of PCA 10, or even the operation of processor 15 itself. EMI may adversely affect the operation of a given component either by inducing unwanted currents into the component itself or into circuit lines on PCB 11. In either case, EMI may cause erroneous operation of either processor 15 or any device coupled to nearby signal traces when EMI shield 100 and/or heat sink 101 are not present.

In addition to processor 15, various embodiments of EMI shield 100 and or heat sink 101 may be used with other components as well. For example, an embodiment of EMI shield 100 may be used to shield surrounding components and circuit traces from EMI generated by integrated circuit 13. An embodiment of heat sink 101 may also be used with integrated circuit 13. In general, various embodiments of EMI shield 100 may be used with any component that may generate electromagnetic energy that may interfere with the operation of other components. The specific dimensions, of each embodiment of EMI shield 100 may be customized for the specific component for which it is to be used. Similarly, the specific shape of various embodiments of EMI shield 100 and or heat sink 101 may also be customized to fit the specific component for which it is to be used.

EMI shield 100, heat sink 101, and a ground plane of PCB 11 may effectively form a conductive box around processor 15. In particular, the bottom side of the box may be formed by the ground plane, the sides of the box may be formed by the sides of EMI shield 100, and the top of the box may be formed by the bottom side of heat sink 101. This may provide an effective method for containing electromagnetic energy radiated from processor 15, and will be discussed in further detail below.

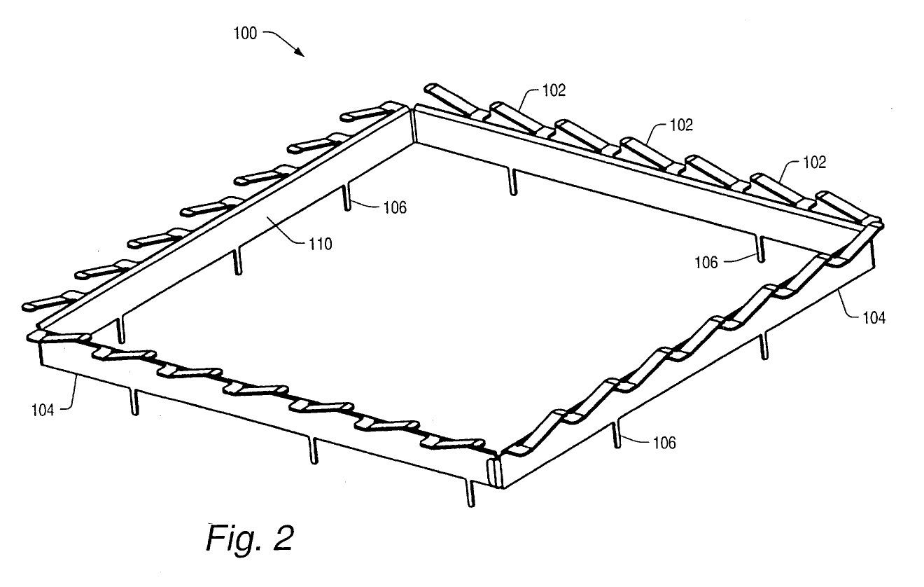

Moving now to FIG. 2, a perspective view of one embodiment of EMI shield 100 is shown. The embodiment shown of EMI shield 100 may be configured for providing shielding to a processor or other type of electronic component having a square shape. EMI shields having other shapes (e.g. rectangular, etc.) are possible and contemplated.

EMI shield 100 may be made of an electrically conductive material. These materials may include, but are not limited to, copper, aluminum, or any other material that is a good electrical conductor. In addition, the material for EMI shield 100 may also be selected based on its abilities to conduct heat. Constructing EMI shield 100 from a material that is both a good electrical conductor and a good heat conductor may significantly improve its performance in shielding electromagnetic energy and conducting heat away from an electronic component.

EMI shield 100 may have an open top, which may allow heat generated during the operation of the electronic component to escape. Furthermore, the open top of EMI shield may allow for the mounting of a heat sink on the top of the electronic component, which may further aid in conducting heat away from the electronic component. EMI shield may be mounted to a printed circuit board (PCB). Pins 106, which extend from the bottom of each side of EMI shield 100, may be inserted into corresponding mounting holes on the PCB. In some embodiments, pins 106 may be electrically coupled to a around plane in a PCB. Electrically coupling pins 106 to a around plane may provide an electrical path to drain the electrical energy absorbed by EMI shield 100.

EMI shield 100 includes a plurality of sides 104. The electronic component with which EMI shield 100 is associated may be mounted within the periphery defined by the plurality of sides 104. Each of the plurality of sides 104 may be in close proximity to the electronic component when mounted around an electronic component. EMI shield 100 may be mounted to the PCB in such a manner that the bottom of each of the plurality of sides 104 is flush with the PCB. The flush mounting of EMI shield 100 may prevent electromagnetic energy from escaping from the sides of the electronic component.

Each of the plurality of sides 104 may include a flange 110 at its top. Each flange 110 may extend in a perpendicular manner from the top of each side 104. A plurality of tabs 102 may extend from each of the flanges. Each tab 102 may include a first portion, a second portion, and a third portion. The first portion may extend from the flange, and may be co-planar to the flange as well. A second portion may extend at an angle to the flange, with a longitudinal axis that is parallel to the longitudinal axis of the flange. In some embodiments, a third portion may extend at an angle from the second portion. Tabs 102 will be discussed in greater detail below.

Each flange 110 and its associated tabs 102 may effectively block electromagnetic fringing occurring near the periphery of an electronic component. In some cases, integrated circuits include a large number of drivers located on their periphery. The switching of these drivers may be a significant source of electromagnetic energy. Thus, the sides 104, flanges 110, and tabs 102 may block electromagnetic fringing near the periphery of an integrated circuit package.

In addition to preventing electromagnetic energy from escaping near the periphery of an electronic component, flanges 110 and tabs 102 may also aid in the conduction of heat away from an electronic component. In particular, tabs 102 may provide additional surface area which may conduct heat and allow it to be radiated away from the electronic component. This may aid in preventing erroneous operation from overheating, or other heat-related problems.

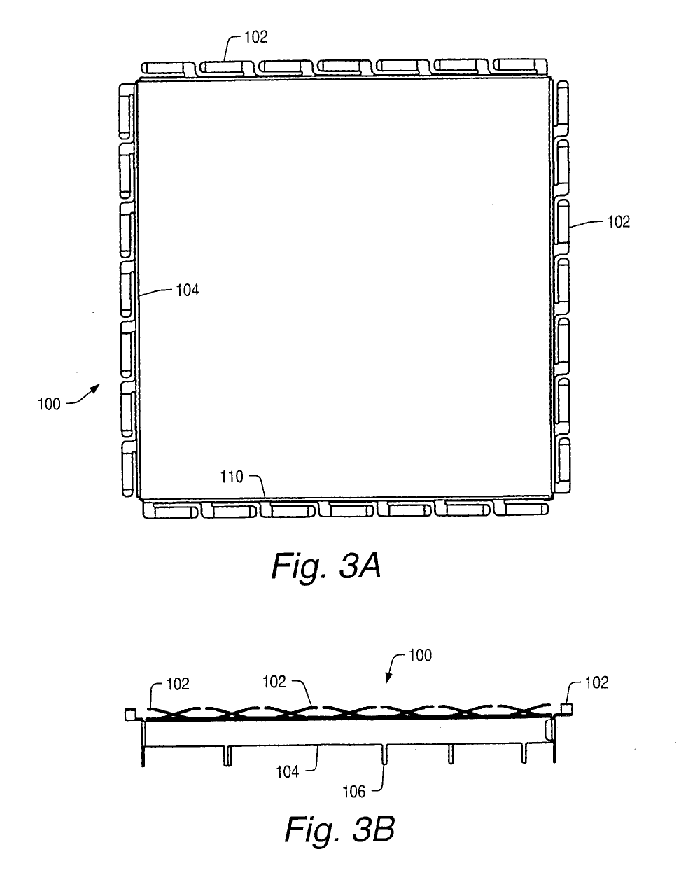

Turning now to FIG. 3A, a top view of one embodiment of EMI shield 100 is shown. In this particular embodiment, the periphery formed by the plurality of sides 104 is square in shape. Other shapes are possible and contemplated, and in general, the shape may be customized to the particular component for which shielding is to be provided. EMI shield 100 also includes a flange 110 at the top of each side 104.

In the embodiment shown in FIG. 3A, EMI shield 100 has an open top. The open top may allow for additional waste heat to be radiated away from it, in contrast to EMI shields with an enclosed top. Furthermore, the open top of EMI shield 100 may allow for the placement of a heat sink, further increasing the ability to radiate waste heat away from the electronic component.

FIG. 3B is a side view of one embodiment of EMI shield 100. In this drawing of EMI shield 100, tabs 102 can be seen as extending from the flanges 110. In particular, the angle of the second portion of tabs 102 may be clearly seen in this drawing. Extending the second portion of tabs 102 at angles from flanges 110 may allow for additional air circulation, which may further promote the radiation of waste heat away from an the electronic component which is being shielded. FIG. 3B also illustrates sides 104 and pins 106. The sides 104 of EMI shield 100 may be mounted such that they are flush with a printed circuit board (PCB), such as PCB 11 of FIG. 1, which may aid in preventing the leakage of electromagnetic energy from processor 15. Pins 106 may be inserted into plated through holes of the PCB, and may be electrically coupled to a ground plane. In one embodiment, pins 106 may be soldered in the plated through holes, thereby providing a secure physical and electrical connection to the ground plane. By electrically connecting pins 106 to a ground plane, electrical energy absorbed by EMI shield 100 may be drained to ground.

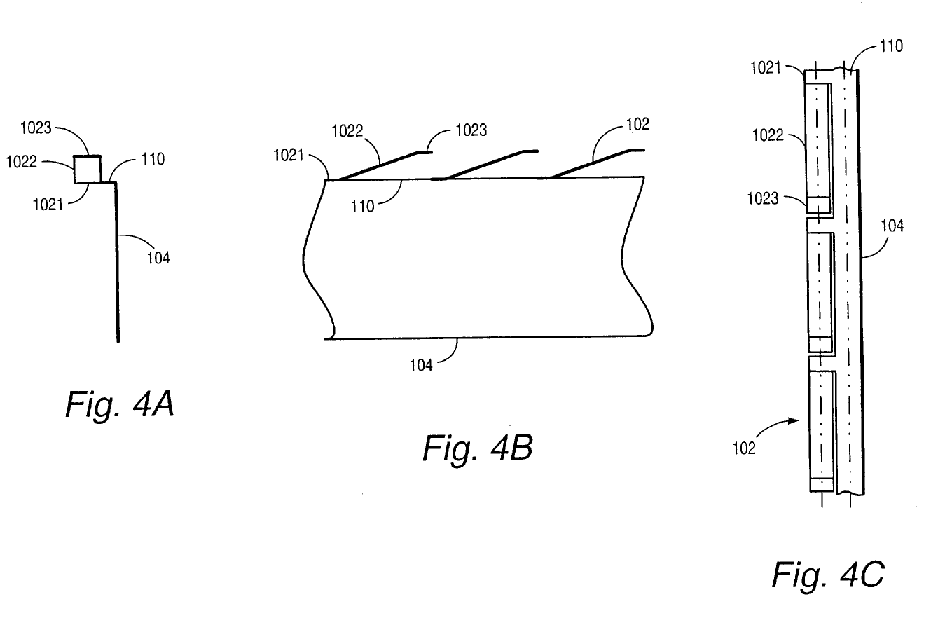

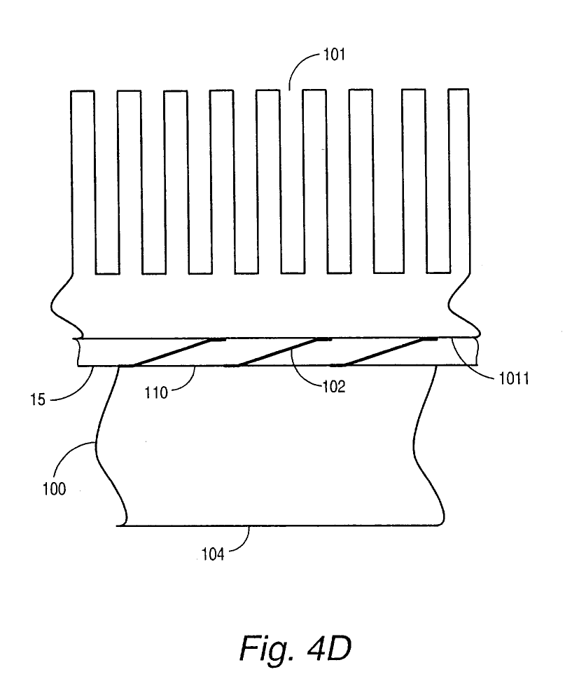

FIGS. 4A, 4B, and 4C illustrate EMI shield 100 in more detail. FIG. 4A is a cross section illustrating flange 110 and a plurality of tabs 102 extending from one side of an embodiment of EMI shield 100. In the embodiment shown, flange 110 extends in a perpendicular manner from side 104 of EMI shield 100. First portion 1021 of a tab may extend further from flange 110. First portion 1021 may be coplanar to flange 110. A second portion 1022 and a third portion 1023 may be present in various embodiments as well.

FIG. 4B is a side view illustrating the plurality of tabs 102 for one embodiment of EMI shield 100. As shown in FIG. 4B, the second portion 1022 of tab 102 extends from first portion 1022 at an angle. The angle may be varied for different embodiments, and may be an up angle or a down angle relative to first portion 1021. A third portion 1023 may extend at an angle from second portion 1022.

Constructing tabs 102 such that second portion 1022 is at an angle relative to first portion 1021 may allow additional air circulation in the vicinity of the tabs while still providing the necessary material EMI shielding. The additional air circulation may allow for more waste heat to be radiated away from an electronic component (e.g. a processor) associated with EMI shield 100. The combination of flange 110 and tabs 102 may block a significant amount of electromagnetic fringing near the periphery of the integrated circuit or other electronic component. Sides 104 of EMI shield 100 may prevent further leakage of electromagnetic energy.

FIG. 4C is a top view illustrating a plurality of tabs 102 for one embodiment of EMI shield 100. As shown in the previous drawings, tabs 102 include a first portion 1021, a second portion 1022, and a third portion 1023. First portion 1021 extends from flange 110, while second portion 1022 extends from first portion 1021. Third portion 1023 extends from second portion 1022. In the embodiment shown, the longitudinal axis of second portion 1022 may be parallel to the longitudinal axis of flange 110. This may minimize the size of any gaps in the areas where electromagnetic energy might escape. However, it should be noted that other embodiments are possible and contemplated wherein the longitudinal axis of a tab 102 is not parallel with the longitudinal axis of flange 110.

Turning now to FIG. 4D, a side view illustrating the coupling of one embodiment of a heat sink to the plurality of tabs for one embodiment of an EMI shield is shown. Heat sink 101 may be mounted on top of processor 15. A bottom side 1011 of heat sink may extend beyond the periphery of processor 15 such that it is in contact with the plurality of tabs 102 if EMI shield 100. As previously noted, heat sink 101 may be coated with an electrically conductive material. Embodiments are also possible and contemplated wherein heat sink 101 is made entirely of an electrically conductive material. The electrically conductive coating of heat sink 101 may be effective at containing electromagnetic energy generated by processor 15 (or other electronic component to which an embodiment of heat sink 101 may be coupled).

Coupling bottom side 1011 of heat sink 101 to the plurality of tabs may provide an electrical path to ground through EMI shield 100. Thus, electromagnetic energy absorbed by the electrically conductive coating of heat sink 101 may be drained to ground through tabs 102 and pins 106 of EMI shield 100.

The effectiveness of EMI shield 100 may be further increased by the manner in which heat sink 101 is mounted. In some embodiments, heat sink 101 may be mounted such that the plurality of tabs is forced downward (i.e. the angle between the first and second portions of tabs 102 is reduced). This may reduce the size of any gaps between tabs 102, which may further aid in containing electromagnetic energy which otherwise might escape.

By using heat sink 101 for EMI shielding, the thermal path from the integrated circuit (e.g. processor 15) may be preserved while still providing a maximum amount of EMI shielding. In the embodiment shown, processor 15 may be effectively enclosed in a metal box that contains any generated electromagnetic energy. A bottom side of the box may be a ground plane within a PCB (e.g. PCB 11 of FIG. 1) to which processor 15 is mounted. EMI shield 100 may also be mounted to the PCB, with processor 15, with pins 106 electrically coupled to the ground plane as described above in reference to FIG. 3B. The sides of the box may be provided by sides 104 of EMI shield 100, which may be mounted flush to the PCB. The top side of the box may be provided by the bottom side of heat sink 101, which may be mounted such that it is in physical contact with both the top of processor 15 and the tabs of EMI shield 100 as shown in FIG. 4D. Thus, processor 15 may be effectively enclosed within a metal box without destroying a thermal path from processor 15. This may allow for effective electromagnetic shielding as well as allowing for effectively radiating waste heat away from processor 15.

While the present invention has been described with reference to particular lo embodiments, it will be understood that the embodiments are illustrative and that the invention scope is not so limited. Any variations, modifications, additions, and improvements to the embodiments described are possible. These variations, modifications, additions, and improvements may fall within the scope of the inventions as detailed within the following claims.

What is claimed is:

1. A shield for containing electromagnetic energy, the shield comprising:
a plurality of sides, wherein each side has a top and a bottom;
a flange extending from the top of each of the plurality of sides, wherein the flange extends perpendicularly from its associated side; and
a plurality of tabs extending from each flange, wherein each of the tabs includes a first portion that extends from the flange and is coplanar to the flange, and a second portion that extends at an angle from the first portion, wherein the longitudinal axis of the second portion is parallel to the longitudinal axis of the flange.

2. The shield as recited in claim 1, wherein each of the plurality of tabs includes a third portion, wherein the third portion extends at an angle from the second portion.

3. The shield as recited in claim 1, wherein the shield is comprised of an electrically conductive material.

4. The shield as recited in claim 1, wherein the shield has a top, wherein the top is open.

5. The shield as recited in claim 1, wherein the shield is configured for mounting to a printed circuit board.

6. The shield as recited in claim 5, wherein the shield is mounted such that the bottom of each of the plurality of sides is flush to the printed circuit board.

7. The shield as recited in claim 5, wherein the shield is configured such that a periphery is defined by the plurality of sides, and wherein the electronic device is mounted within the periphery.

8. The shield as recited in claim 7, wherein the electronic device is a processor.

9. A method for containing electromagnetic energy generated by a component, the method comprising:
providing a printed circuit board, wherein an electronic device is mounted to the printed circuit board; and
mounting a shield to the printed circuit board, the shield comprising:
a plurality of sides, wherein each side has a top and a bottom;
a flange extending from the top of each of the plurality of sides, wherein the flange extends perpendicularly from its associated side; and
a plurality of tabs extending from each flange, wherein each of the tabs includes a first portion that extends from the flange and is coplanar to the flange, and a second portion that extends at an angle from the first portion, wherein the longitudinal axis of the second portion is parallel to the longitudinal axis of the flange;
wherein the electronic device is mounted within a periphery defined by the plurality of sides of the shield.

10. The method as recited in claim 9, wherein each of the plurality of tabs includes a third portion, wherein the third portion extends at an angle from the second portion.

11. The method as recited in claim 9, wherein the shield is comprised of an electrically conductive material.

12. The method as recited in claim 9, wherein the shield is comprised of an electrically conductive material.

13. The method as recited in claim 9, wherein the shield is mounted flush to the printed circuit board.

14. The method as recited in claim 9, wherein the shield is configured such that a periphery is defined by the plurality of sides, and wherein the electronic device is mounted within the periphery.

15. The method as recited in claim 14, wherein the electronic device is a processor.

16. A printed circuit assembly comprising:
a printed circuit board;
an electronic device mounted to the printed circuit board;
a shield comprising:
a plurality of sides, wherein each side has a top and a bottom;
a flange extending from the top of each of the plurality of sides, wherein the flange extends perpendicularly from its associated side; and
a plurality of tabs extending from each flange, wherein each of the tabs includes a first portion that extends from the flange and is coplanar to the flange, and a second portion that extends at an angle from the first portion, wherein the longitudinal axis of the second portion is parallel to the longitudinal axis of the flange;
wherein the electronic device is mounted within a periphery defined by the plurality of sides of the shield; and
a heat sink, wherein the heat sink is coated with an electrically conductive material wherein a bottom side of the heat sink is physically coupled to the plurality of tabs of the heat shield.

17. The printed circuit assembly as recited in claim 16, wherein each of the plurality of tabs includes a third portion, wherein the third portion extends at an angle from the second portion.

18. The printed circuit assembly as recited in claim 16, wherein the shield is comprised of an electrically conductive material.

19. The printed circuit assembly as recited in claim 16, wherein the shield has a top, wherein the top is open.

20. The printed circuit assembly as recited in claim 16, wherein the shield is mounted such that each of the plurality of sides is flush to the printed circuit board.

21. The printed circuit assembly as recited in claim 16, wherein the shield is configured such that a periphery is defined by the plurality of sides, and wherein the electronic device is mounted within the periphery.

22. The printed circuit assembly as recited in claim 21, wherein the electronic device is a processor.

23. A shielding apparatus for containing electromagnetic energy, the shielding apparatus comprising:
a shield comprised of an electrically conductive material, the shield including:
a plurality of sides, wherein each side has a top and a bottom;
a flange extending from the top of each of the plurality of sides, wherein the flange extends perpendicularly from its associated side; and
a plurality of tabs extending from each flange, wherein each of the tabs includes a first portion that extends from the flange and is coplanar to the flange, and
a second portion that extends at an angle from the first portion, wherein the longitudinal axis of the second portion is parallel to the longitudinal axis of the flange; and
a heat sink, wherein the heat sink is coated with an electrically conductive material;
wherein a bottom side of the heat sink is physically coupled to the plurality of tabs of the heat shield.

24. The shielding apparatus as recited in claim 23, wherein each of the plurality of tabs includes a third portion, wherein the third portion extends at an angle from the second portion, and wherein the bottom side of the heat sink is physically and electrically coupled to the third portion.

25. The shielding apparatus as recited in claim 23, wherein the shield is configured for mounting to a printed circuit board.

26. The shielding apparatus as recited in claim 25, wherein the shield is mounted such that the bottom of each of the plurality of sides is flush to the printed circuit board.

27. The shielding apparatus as recited in claim 25, wherein the shield is configured such that a periphery is defined by the plurality of sides, and wherein the electronic device is mounted within the periphery.

28. The shielding apparatus as recited in claim 27, wherein the electronic device is a processor.

29. The shielding apparatus as recited in claim 23, wherein the bottom side of the heat sink is coupled to a top side of the processor.

30. A method for containing electromagnetic energy generated by a component, the method comprising:
providing a printed circuit board, wherein an electronic device is mounted to the printed circuit board; and
mounting a shield to the printed circuit board, the shield comprising:
a plurality of sides, wherein each side has a top and a bottom;
a flange extending from the top of each of the plurality of sides, wherein the flange extends perpendicularly from its associated side; and
a plurality of tabs extending from each flange, wherein each of the tabs includes a first portion that extends from the flange and is coplanar to the flange, and a second portion that extends at an angle from the first portion, wherein the longitudinal axis of the second portion is parallel to the longitudinal axis of the flange, wherein the electronic device is mounted within a periphery defined by the plurality of sides of the shield, and wherein the shield is made of an electrically conductive material; and
coupling a heat sink to the shield, wherein a bottom side of the heat sink is coupled to the plurality of tabs, wherein the heat sink is coated with an electrically conductive material.

31. The method as recited in claim 30, wherein each of the plurality of tabs includes a third portion, wherein the third portion extends at an angle from the second portion, and wherein the bottom of the heat sink is physically and electrically coupled to the third portion.

32. The method as recited in claim 30 wherein the shield is mounted flush to the printed circuit board.
